(19) United States
(12) Patent Application Publication
(10) Pub. No.: US 2026/0033292 A1
(43) Pub. Date: Jan. 29, 2026

(54) SUBSTRATE SUPPORT, SUBSTRATE PROCESSING APPARATUS, AND SUBSTRATE SUPPORT PRODUCTION METHOD

(71) Applicant: Tokyo Electron Limited, Tokyo (JP)

(72) Inventors: Toshikazu AKIMOTO, Tokyo (JP); Naoki UMESHITA, Tokyo (JP); Hiroyuki OMIYA, Tokyo (JP); Shinichi TANABE, Tokyo (JP)

(73) Assignee: Tokyo Electron Limited, Tokyo (JP)

(21) Appl. No.: 19/344,667

(22) Filed: Sep. 30, 2025

Related U.S. Application Data
(63) Continuation of application No. PCT/JP2024/011539, filed on Mar. 25, 2024.

(30) Foreign Application Priority Data
Apr. 7, 2023 (JP) 2023-062480

(51) Int. Cl. H01L 21/687

(52) U.S. Cl. CPC H01L 21/68757

(57) ABSTRACT

A substrate support includes a support and a gel member. The support is for supporting a substrate. The gel member is provided at a location of the support in contact with the substrate and is made of a gel holding a solvent by a polymer network.

### CROSS-REFERENCE TO RELATED APPLICATIONS

This application is a bypass continuation application of international application No. PCT/JP2024/011539 having an international filing date of Mar. 25, 2024 and designating the United States, the international application being based upon and claiming the benefit of priority from Japanese Patent Application No. 2023-062480, filed on Apr. 7, 2023, the entire contents of each are incorporated herein by reference.

### TECHNICAL FIELD

The present disclosure relates to a substrate support, a substrate processing apparatus, and a substrate support production method.

### BACKGROUND

PTL 1 below discloses “a substrate support for use in a reaction chamber of a plasma processing apparatus, the substrate support including: a ceramic member; a metal heat transfer member located above the ceramic member, the metal heat transfer member having a maximum thickness of about ¼ inches and including at least one flow path through which a liquid can circulate in order to perform at least one of heating and cooling at the heat transfer member; and an electrostatic chuck located above the heat transfer member and having a support surface for supporting a substrate in the reaction chamber of the plasma processing apparatus”.

### CITATION LIST

### Patent Documents

PTL 1: JP2012-099825A

### SUMMARY

The present disclosure provides a technique for preventing occurrence of substrate damage.

A substrate support according to an aspect of the present disclosure includes a support and a gel member. The support is configured to support a substrate. The gel member is provided at a location of the support in contact with the substrate and is made of a gel holding a solvent by a polymer network.

According to the present disclosure, it is possible to prevent occurrence of substrate damage.

### BRIEF DESCRIPTION OF DRAWINGS

FIG. 1 is a diagram schematically illustrating an example of a configuration of a substrate processing apparatus according to an embodiment.

FIG. 2A is a diagram illustrating an example in which a gel member is provided at a location in contact with a substrate according to the embodiment.

FIG. 2B is a diagram illustrating an example in which a gel member is provided at a location in contact with the substrate according to the embodiment.

FIG. 2C is a diagram illustrating an example in which a gel member is provided at a location in contact with the substrate according to the embodiment.

FIG. 3 is a diagram illustrating an example of a preparation method using amorphous coordination polymerization.

FIG. 4 is a diagram illustrating an example of a first preparation method using physical crosslinking.

### DETAILED DESCRIPTION

Hereinafter, an embodiment of a substrate support, a substrate processing apparatus, and a substrate support production method disclosed in the present application will be described in detail with reference to the drawings. The present disclosure is not limited to the substrate support, the substrate processing apparatus, and the substrate support production method disclosed by the embodiment.

In substrate processing, a substrate such as a semiconductor wafer is transferred to a substrate processing apparatus, and substrate processing is performed. However, when the substrate is transferred or the like, the substrate may be damaged by physical contact, and particles may be generated. Damage or particles on the substrate may serve as a starting point to cause loss of surface flatness, and a focal shift may occur in an exposure process for exposing the substrate later.

### EMBODIMENT

### [System Configuration]

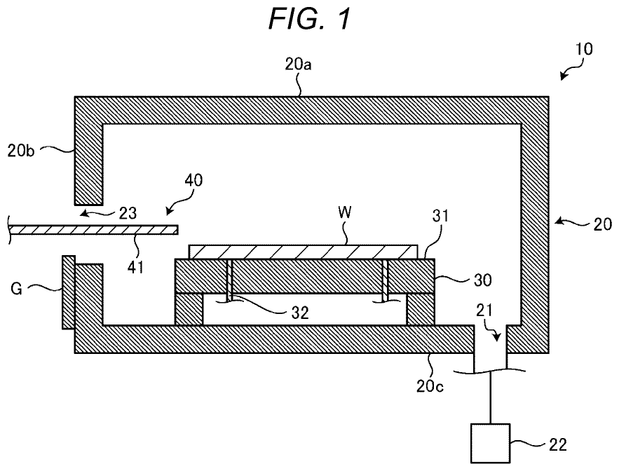

Embodiments will be described. FIG. 1 is a diagram schematically illustrating an example of a configuration of a substrate processing apparatus 10 according to the embodiment. The substrate processing apparatus 10 is an apparatus that performs substrate processing such as etching, film formation, or ashing on a substrate W such as a semiconductor wafer. The substrate processing apparatus 10 includes a chamber 20 and a stage 30.

The inside of the chamber 20 is configured to be airtight. The chamber 20 has a top wall portion 20a and a bottom wall portion 20c, and a sidewall portion 20b connecting therebetween.

An exhaust port 21 is formed in the bottom wall portion 20c of the chamber 20. An exhaust system 22 is connected to the chamber 20 through the exhaust port 21. The exhaust system 22 includes a vacuum pump and a pressure control valve. The exhaust system 22 can adjust pressure in the chamber 20 by controlling the vacuum pump and the pressure control valve. As the vacuum pump, for example, a dry pump or a turbomolecular pump can be used. The exhaust system 22 performs evacuation and reduces pressure in the chamber 20 to reach a predetermined vacuum degree suitable for substrate processing.

The stage 30 is disposed in the chamber 20. The stage 30 may be formed in a disk shape. A placement surface 31 where the substrate W is to be placed is formed at an upper surface of the stage 30. An electrostatic chuck may be provided on the upper surface of the stage 30, and an upper surface of the electrostatic chuck may be the placement surface 31. In addition, a ring member such as a focus ring may be disposed around the substrate W.

A plurality of through-holes (for example, three) is formed in the stage 30. Each through-hole is provided with a lift pin 32. The lift pin 32 can be lifted and lowered by an elevation mechanism (not illustrated).

An opening 23 for loading the substrate W into the chamber 20 and unloading the substrate W from the inside of the chamber 20 is formed in the sidewall portion 20b of the chamber 20. The opening 23 is opened and closed by a gate valve G.

The substrate W is transferred by a transfer mechanism 40 such as a transfer arm and placed on the placement surface 31 of the stage 30. The transfer mechanism 40 includes a pick 41 on a distal end side. The transfer mechanism 40 supports and transfers the substrate W by the pick 41.

When the substrate W is loaded into the stage 30 and unloaded from the stage 30, the substrate processing apparatus 10 lifts the lift pin 32 by the elevation mechanism. The lift pin 32 supports the substrate W at a distal end and transfers the substrate W to and from the pick 41. When the substrate W is supported by the stage 30, the substrate processing apparatus 10 lowers the lift pin 32 by the elevation mechanism and accommodates the lift pin 32 in the stage 30. Accordingly, the substrate W supported by the lift pin 32 is placed on the placement surface 31. In the embodiment, the stage 30, the lift pin 32, and the pick 41 correspond to a support in the present disclosure.

The substrate W may be damaged by physical contact with the transfer mechanism 40, the lift pin 32, the stage 30, or the like, and particles may be generated.

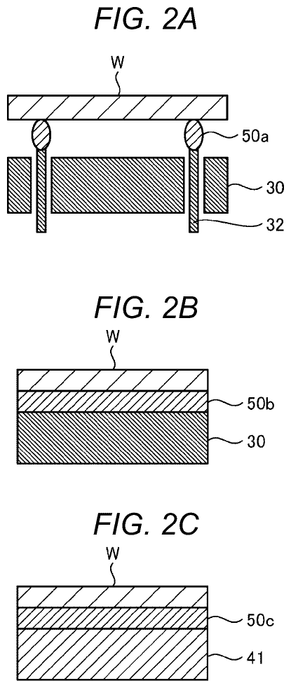

Therefore, in order to prevent the substrate W from being damaged, the substrate processing apparatus 10 is provided with a gel member made of a gel at a location in contact with the substrate W. FIGS. 2A to 2C are diagrams illustrating examples in which gel members are provided at locations in contact with the substrate W according to the embodiment. FIG. 2A illustrates a case where a gel member 50a is provided at the distal end of the lift pin 32 as the location in contact with the substrate W. The substrate W comes into contact with the lift pin 32 via the gel member 50a. The gel member 50a prevents physical contact between the substrate W and the lift pin 32, and also functions as a cushion member. Thus, the gel member 50a can prevent occurrence of damage to the substrate W due to contact with the lift pin 32. In FIG. 2B, a gel member 50b is provided at the placement surface 31 of the stage 30 as the location in contact with the substrate W. The substrate W comes into contact with the placement surface 31 of the stage 30 via the gel member 50b. The gel member 50b prevents physical contact between the substrate W and the placement surface 31, and also functions as a cushion member. Thus, the gel member 50b can prevent occurrence of damage to the substrate W due to contact with the placement surface 31. FIG. 2C illustrates a case where a gel member 50c is provided at the pick 41 of the transfer mechanism 40 as the location in contact with the substrate W. The substrate W comes into contact with the pick 41 via the gel member 50c. The gel member 50c prevents physical contact between the substrate W and the pick 41, and also functions as a cushion member. Thus, the gel member 50c can prevent occurrence of damage to the substrate W due to contact with the pick 41. Locations where the gel member is provided are not limited to those in FIGS. 2A to 2C. The gel member may be provided at any location in contact with the substrate W.

### [Gel]

Next, the gel will be described. The gel includes a gel that contains a solvent and a gel that does not contain any solvent. The gel that contains the solvent is in a state where the solvent is trapped in a polymer network (mesh), and the solvent is held by the polymer network. The gel that does not contain any solvent is obtained by removing the solvent from the gel that contains the solvent. The gel that does not contain any solvent is referred to as an aerogel. Since the aerogel is mechanically fragile, particles are generated due to physical contact. In addition, the aerogel has low thermal conductivity, and heat is less likely to dissipate when the aerogel is positioned near a heating mechanism. In contrast, the gel containing the solvent has elasticity, high mechanical strength, and high thermal conductivity. Therefore, the gel containing the solvent is suitable for the gel member.

In the gel that contains the solvent, the solvent volatilizes when the solvent is a volatile liquid such as water. In a case where the gel containing the volatile liquid as the solvent is disposed in the chamber 20, when the pressure in the chamber 20 is reduced to reach the predetermined vacuum degree suitable for substrate processing, the solvent volatilizes from the gel and causes contamination in the chamber 20. In addition, in general, the transfer mechanism 40 is also disposed in a reduced-pressure transfer chamber, and in this case as well, the solvent volatilized from the gel may cause contamination. The reduced-pressure environment inside the substrate processing apparatus 10 is not always constant and is exposed to a large pressure fluctuation such as returning to atmospheric pressure during maintenance or the like, and thus volatilization from the solvent becomes a problem each time. Therefore, the gel members 50a to 50c are formed of a gel in which the solvent is an ionic liquid. Accordingly, the gel members 50a to 50c are resistant to solvent volatilization even in a vacuum and also function as cushion materials, and thus, even in a reduced-pressure environment such as in the chamber 20, occurrence of damage to the substrate W can be prevented while maintaining the reduced-pressure environment.

### [Ionic Liquid]

Next, the ionic liquid will be described. The ionic liquid is an ionic compound that is a liquid at room temperature, and is also referred to as a room temperature molten salt. The ionic liquid has characteristics such as almost zero vapor pressure and non-volatility (does not volatilize even at a high temperature or in a vacuum). The ionic liquid contains positively charged ions (cations) and negatively charged ions (anions).

Examples of the cations constituting the ionic liquid include nitrogen-containing cations such as a pyridinium-type, an imidazolium-type, an ammonium-type, a pyrrolidinium-type, a piperidinium-type, and phosphorus-containing cations such as a phosphonium-type. These cations contain an alkyl group such as —(CH₂)ₙCH₃ as a side chain. Other examples of the cations constituting the ionic liquid include a morphonium-type and a sulfonium-type.

Examples of the pyridinium-type cations include, but are not limited to, C₂pym⁺ represented by chemical formula (C1-1) and C₄py⁺ represented by chemical formula (C1-2).

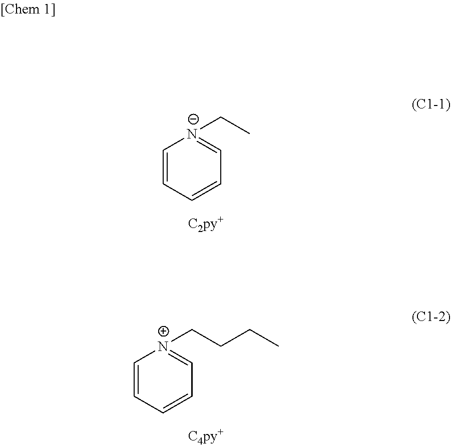

Examples of the imidazolium-type cations include, but are not limited to, C₂mimm⁺ represented by chemical formula (C2-1), C₄mim⁺ represented by chemical formula (C2-2), C₆mim⁺ represented by chemical formula (C2-3), and C₈mim⁺ represented by chemical formula (C2-4).

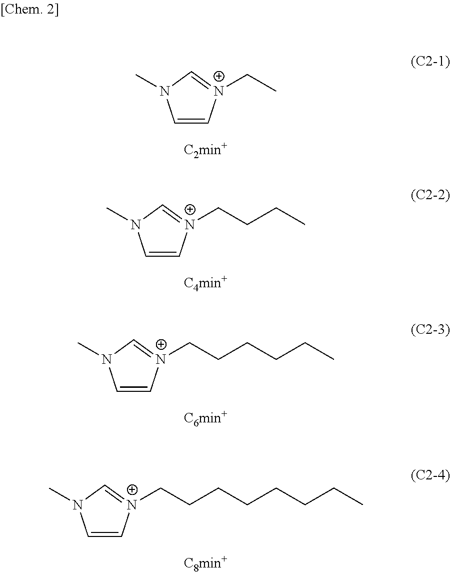

Examples of the ammonium-type cations include, but are not limited to, N_{3,1,1,1}⁺ represented by chemical formula (C3-1), N_{4,1,1,1}⁺ represented by chemical formula (C3-2), N_{6,1,1,1}⁺ represented by chemical formula (C3-3), N_{2,2,1,(2O1)}⁺ represented by chemical formula (C3-4), and Ch⁺ represented by chemical formula (C3-5).

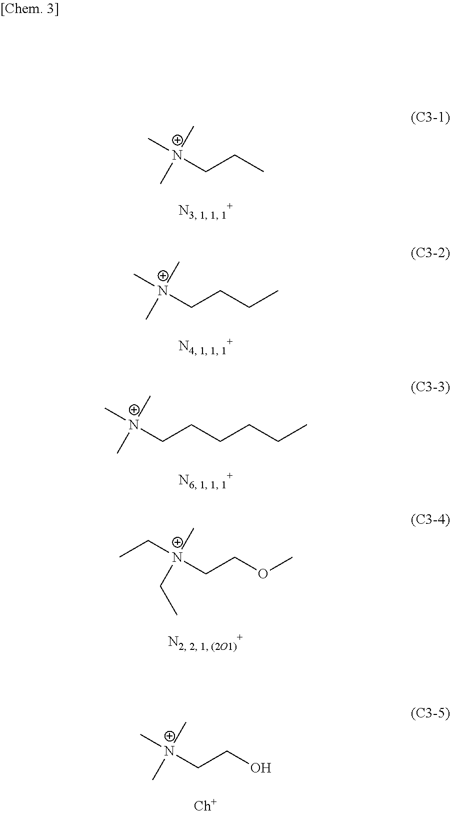

Examples of the pyrrolidinium-type cations include, but are not limited to, Pyr_{1,3}⁺ represented by chemical formula (C4-1) and Pyr_{1,4}⁺ represented by chemical formula (C4-2).

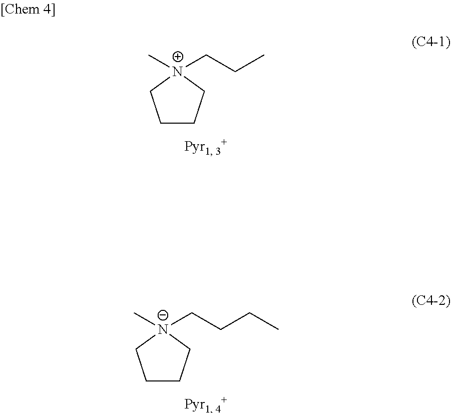

Examples of the piperidinium-type cations include, but are not limited to, Pip_{1,3}⁺ represented by chemical formula (C5-1) and Pip_{1,4}⁺ represented by chemical formula (C5-2).

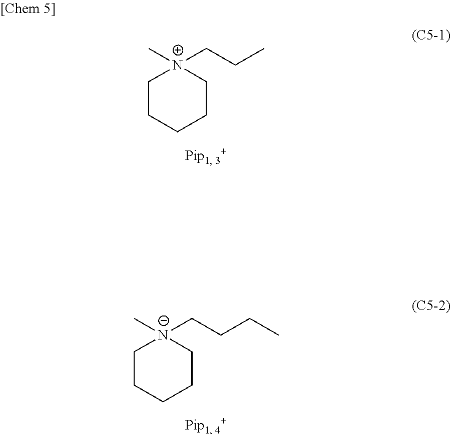

Examples of the phosphonium-type cations include, but are not limited to, P_{5,2,2,2}⁺ represented by chemical formula (C6-1) and P_{6,6,6,14}⁺ represented by chemical formula (C6-2).

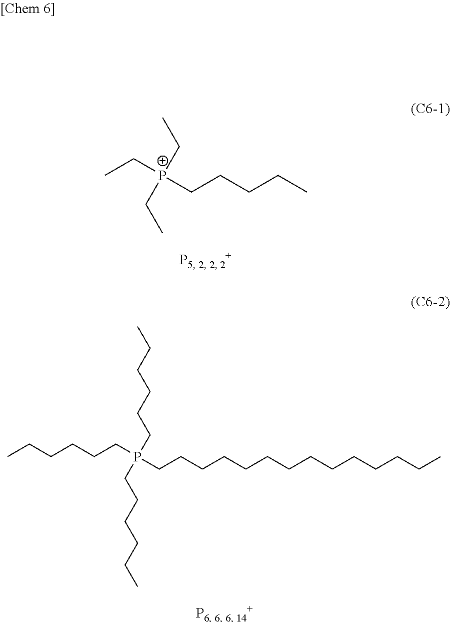

Examples of the anions constituting the ionic liquid include, but are not limited to TfO⁻ represented by chemical formula (A1), Tf₂N⁻ (TFSA⁻) represented by chemical formula (A2), Tf₃C⁻ represented by chemical formula (A3), FSA⁻ represented by chemical formula (A4), CH₃COO⁻ represented by chemical formula (A5), CF₃COO⁻ represented by chemical formula (A6), BF₄⁻ represented by chemical formula (A7), PF₆⁻ represented by chemical formula (A8), (CN)₂N⁻ represented by chemical formula (A9), AlCl₄⁻ represented by chemical formula (A10), and Al₂Cl₇⁻ represented by chemical formula (A11). Other examples of the anions constituting the ionic liquid include PF₆⁻ and Cl⁻.

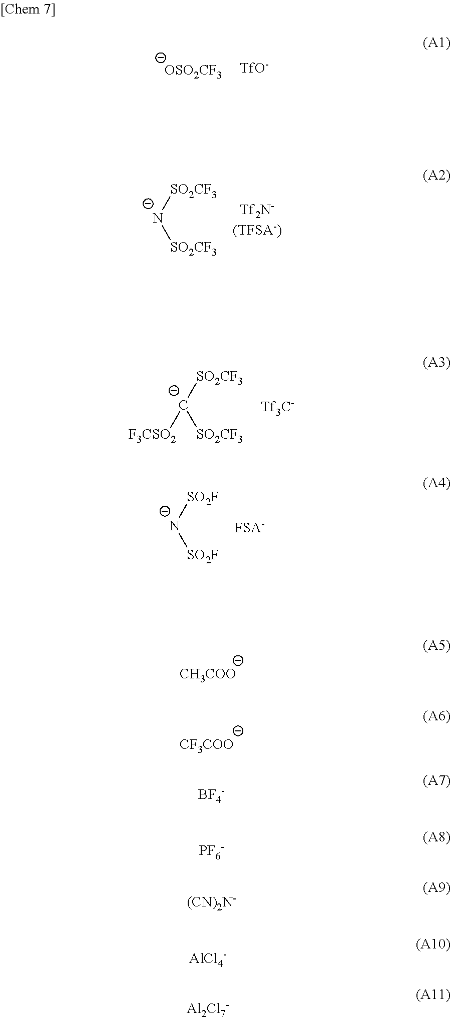

Specific examples of the ionic liquid include N,N-diethyl-N-methyl-N-(2-methoxyethyl)ammonium bis(trifluoromethanesulfonyl)imide (DEME·TFSA) and 1-ethyl-3-methylimidazolium dicyanamide.

### [Method for Preparing Gel]

Next, a method for preparing the gel will be described. The method for preparing the gel includes a preparation method using amorphous coordination polymerization, a preparation method using physical crosslinking, and a preparation method using chemical crosslinking.

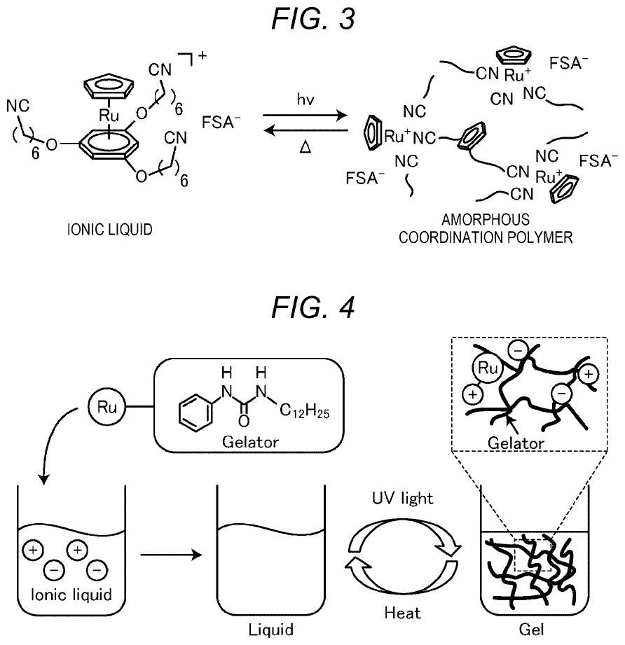

The preparation method using amorphous coordination polymerization is a method of gelation by subjecting the ionic liquid to light irradiation or thermal conversion to induce amorphous coordination polymerization. FIG. 3 is a diagram illustrating an example of the preparation method using amorphous coordination polymerization. The ionic liquid capable of amorphous coordination polymerization is shown on a left side in FIG. 3. The ionic liquid contains ruthenium (Ru) and a side chain of NC. The ionic liquid capable of amorphous coordination polymerization undergoes phase transition between a liquid and a gel due to heat or light. For example, the ionic liquid capable of amorphous coordination polymerization undergoes gelation upon light irradiation and returns to the liquid when applying heat. For example, the ionic liquid on the left side in FIG. 3 is irradiated with ultraviolet rays (for example, having a wavelength of 365 nm) to cause Ru and NC to bind and form an amorphous coordination polymer as on a right side, and thus the ionic liquid is held and undergoes gelation. In addition, in the gel of the amorphous coordination polymer, bonds are broken by applying heat, and the gel returns to the ionic liquid.

The preparation method using physical crosslinking includes a first preparation method and a second preparation method. The first preparation method using physical crosslinking is a method of gelation by mixing the ionic liquid and a gelling agent and crosslinking the gelling agent. As the gelling agent used in the first preparation method using physical crosslinking, there are a photo-responsive gelling agent and a heat-soluble gelling agent.

When the photo-responsive gelling agent is used, the ionic liquid and the photo-responsive gelling agent are mixed and the gelling agent is crosslinked through light irradiation. An example of the photo-responsive gelling agent includes a metal complex coordinated with a low-molecular-weight gelling agent. FIG. 4 is a diagram illustrating an example of the first preparation method using physical crosslinking. FIG. 4 is an example using the photo-responsive gelling agent. The photo-responsive gelling agent contains Ru and a side chain of C₁₂H₂₅. In such a photo-responsive gelling agent, Ru and the side chain of C₁₂H₂₅ are entangled due to light irradiation and the ionic liquid is held by a polymer network of the gelling agent to induce gelation. The photo-responsive gelling agent is heated to break the network and return to the ionic liquid.

When using the heat-soluble gelling agent, the ionic liquid and the heat-soluble gelling agent are mixed, and the gelling agent is crosslinked through heating or cooling. Examples of the heat-soluble gelling agent include glycolipids such as agarose and L-glutamate. Examples of the heat-soluble gelling agent include, but are not limited to, substances having structures represented by chemical formulas (C8-1) to (C8-3).

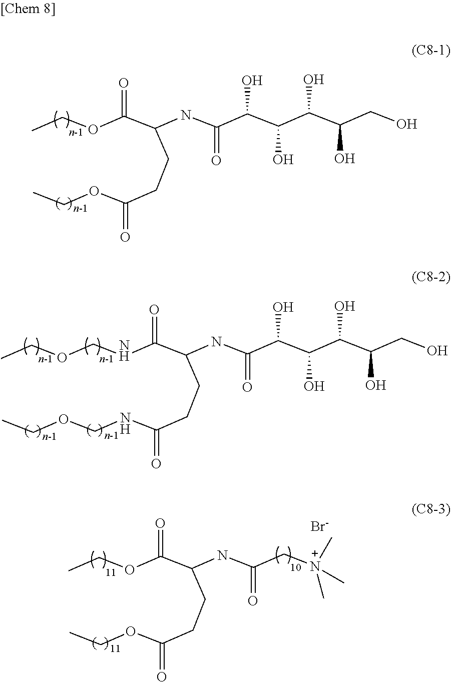

The second preparation method using physical crosslinking is a method of gelation by mixing the ionic liquid and a polymer and holding the ionic liquid by a polymer network. Examples of the polymer include, but are not limited to, poly(vinylidene fluoride-co-hexafluoropropylene) (P(VDF-HFP)), polystyrene (PS), polymethyl methacrylate resin (PMMA), polyethylene glycol (PEO), polyvinylpyrrolidone (PVPyrr), polyvinyl alcohol (PVA), polyacrylonitrile (PAN), polyether sulfone (PES), polyhydroxyethyl methacrylate (pHEMA), PS-PMMA-PS, PS-PEO-PS, PVPyrr-PS, and PS-PMMA.

The preparation method using chemical crosslinking is a method of gelation by mixing the ionic liquid, a monomer of a radical-polymerizable compound, and a photo-radical polymerization initiator or a thermal radical polymerization initiator and crosslinking the monomer through light irradiation or heating.

Examples of the radical-polymerizable compound include, but are not limited to, at least one selected from the group consisting of (meth)acrylic acid, (meth)acrylic acid esters, (meth)acrylamides, and (meth)acrylonitriles.

Examples of the photo-radical polymerization initiator include, but are not limited to, 1-hydroxy-cyclohexyl-phenyl-ketone, 2-hydroxy-2-methyl-1-phenyl-propane-1-one, 2,2-dimethoxy-1,2-diphenylethane-1-one, 2-methyl-1-(4-methylthiophenyl)-2-morpholinopropane-1-one, and 2,4,6-trimethylbenzoyl-diphenyl-phosphine oxide.

Examples of the thermal radical polymerization initiator include peroxides such as t-butyl peroxybenzoate, di-t-butyl peroxide, cumene peroxide, acetyl peroxide, benzoyl peroxide, and lauroyl peroxide. Examples of the thermal radical polymerization initiator include, but are not limited to, azo compounds such as azobisisobutyronitrile, azobis-2,4-dimethylvaleronitrile, and azobiscyclohexanecarbonitrile.

The gel member may be formed by gelation at the location in contact with the substrate W. In addition, the gel member may be formed from a gel prepared in advance and attached to the location in contact with the substrate W.

In the preparation method using amorphous coordination polymerization, after the ionic liquid capable of amorphous coordination polymerization is coated to the contact location, the gel member can be formed at the contact location through light irradiation. In the case of the photo-responsive gelling agent, after the mixed liquid in which the ionic liquid and the photo-responsive gelling agent are mixed is coated to the contact location, the gel member can be formed at the contact location through light irradiation. In the case of the heat-soluble type gelling agent, after the mixed liquid in which the ionic liquid and the heat-soluble gelling agent are mixed is coated to the contact location, the gel member can be formed at the contact location through heating. In the preparation method using chemical crosslinking, after the mixed liquid in which the ionic liquid, the monomer of the radical-polymerizable compound, and the photo-radical polymerization initiator or the thermal radical polymerization initiator are mixed is coated to the contact location, the gel member can be formed at the contact location through light irradiation or heating.

The above-described embodiment has been described using an example in which the substrate processing apparatus 10 is an apparatus that performs substrate processing on the substrate W in the reduced-pressure chamber 20 and the gel member is formed from the gel containing the ionic liquid as the solvent. However, the technique disclosed herein is not limited thereto. The substrate processing apparatus 10 may be an apparatus that performs substrate processing on the substrate W in an atmospheric pressure environment. In this case, the gel member may be formed of a gel containing a volatile liquid as the solvent.

The above embodiment has been described using an example in which the substrate W is a semiconductor wafer. However, the present disclosure is not limited thereto. The substrate W may be a glass substrate or the like.

It shall be understood that the embodiments disclosed herein are illustrative and are not restrictive in all aspects. Indeed, the above-described embodiment can be implemented in various forms. The embodiment described above may be omitted, replaced, or modified in various forms without departing from the scope and spirit of the appended claims.

Further, the following appendixes will be further disclosed with respect to the above-described embodiment.

### (Appendix 1)

A substrate support including:
a support configured to support a substrate, and
a gel member provided at a location of the support in contact with the substrate, the gel member being made of a gel holding a solvent by a polymer network.

### (Appendix 2)

The substrate support according to Appendix 1, in which the solvent is an ionic liquid.

### (Appendix 3)

The substrate support according to Appendix 2, in which the gel is obtained through gelation by subjecting the ionic liquid to light irradiation to induce amorphous coordination polymerization.

### (Appendix 4)

The substrate support according to Appendix 2, in which the gel is obtained through gelation by mixing the ionic liquid and a photo-responsive gelling agent and crosslinking the gelling agent through light irradiation.

### (Appendix 5)

The substrate support according to Appendix 2, in which the gel is obtained through gelation by mixing the ionic liquid and a heat-soluble gelling agent and crosslinking the gelling agent through heating or cooling.

### (Appendix 6)

The substrate support according to Appendix 2, in which the gel is obtained through gelation by mixing the ionic liquid and a polymer and holding the ionic liquid by a mesh of the polymer.

### (Appendix 7)

The substrate support according to Appendix 2, in which the gel is obtained through gelation by mixing the ionic liquid, a monomer of a radical-polymerizable compound, and a photo-radical polymerization initiator or a thermal radical polymerization initiator and crosslinking the monomer through light irradiation or heating.

### (Appendix 8)

The substrate support according to any one of Appendices 3 to 5 and 7, in which the gel member is formed by gelation of the ionic liquid at the contact location.

### (Appendix 9)

The substrate support according to any one of Appendices 1 to 8, in which the support is any one of a stage having a placement surface where the substrate is to be placed, a lift pin configured to be protrudable and retractable from the stage, and a pick, on which the substrate is to be placed, the pick being of a transfer mechanism that transfers the substrate.

### (Appendix 10)

A substrate processing apparatus including:
the substrate support according to any one of Appendices 1 to 9, and
a chamber in which pressure is reducible to reach a predetermined vacuum degree and in which the substrate support is disposed.

### (Appendix 11)

A substrate support production method including: forming a gel member made of a gel holding a solvent by a polymer network at a location of a support in contact with a substrate, the support being configured to support the substrate.

### (Appendix 12)

The substrate support production method according to Appendix 11, in which the gel is formed by subjecting the ionic liquid to light irradiation to induce amorphous coordination polymerization.

### (Appendix 13)

The substrate support production method according to Appendix 11, in which the gel is formed by mixing the ionic liquid and a photo-responsive gelling agent and crosslinking the gelling agent through light irradiation.

### (Appendix 14)

The substrate support production method according to Appendix 11, in which the gel is formed by mixing the ionic liquid and a heat-soluble gelling agent and crosslinking the gelling agent through heating or cooling.

### (Appendix 15)

The substrate support production method according to Appendix 11, in which the gel is formed by mixing the ionic liquid and a polymer and holding the ionic liquid by a mesh of the polymer.

### (Appendix 16)

The substrate support production method according to Appendix 11, in which the gel is formed by mixing the ionic liquid, a monomer of a radical-polymerizable compound, and a photo-radical polymerization initiator or a thermal radical polymerization initiator and crosslinking the monomer through light irradiation or heating.

### (Appendix 17)

The substrate support production method according to Appendix 11, in which the gel member is formed by gelation of an ionic liquid at the contact location.

1. A substrate support comprising:
a support configured to support a substrate, and
a gel member provided at a first location of the support in contact with the substrate, the gel member being made of a gel holding a solvent by a polymer network.

2. The substrate support according to claim 1, wherein
the solvent is an ionic liquid.

3. The substrate support according to claim 2, wherein
the gel is obtained through gelation by subjecting the ionic liquid to light irradiation to induce amorphous coordination polymerization.

4. The substrate support according to claim 2, wherein
the gel is obtained through gelation by mixing the ionic liquid and a photo-responsive gelling agent and crosslinking the gelling agent through light irradiation.

5. The substrate support according to claim 2, wherein
the gel is obtained through gelation by mixing the ionic liquid and a heat-soluble gelling agent and crosslinking the gelling agent through heating or cooling.

6. The substrate support according to claim 2, wherein
the gel is obtained through gelation by mixing the ionic liquid and a polymer and holding the ionic liquid by a mesh of the polymer.

7. The substrate support according to claim 2, wherein
the gel is obtained through gelation by mixing the ionic liquid, a monomer of a radical-polymerizable compound, and a photo-radical polymerization initiator or a thermal radical polymerization initiator and crosslinking the monomer through light irradiation or heating.

8. The substrate support according to claim 3, wherein
the gel member is formed by gelation of the ionic liquid at the first location.

9. The substrate support according to claim 1, wherein
the support is any one of a stage having a placement surface where the substrate is to be placed, a lift pin configured to be protrudable and retractable from the stage, and a pick, on which the substrate is to be placed, of a transfer mechanism that transfers the substrate.

10. A substrate processing apparatus comprising:
the substrate support according to claim 1, and
a chamber in which pressure is reducible to reach a predetermined vacuum degree and in which the substrate support is disposed.

11. A substrate support production method comprising:
forming a gel member made of a gel holding a solvent by a polymer network at a first location of a support in contact with a substrate, the support supporting the substrate.

12. The substrate support production method according to claim 11, wherein
the gel is formed by subjecting an ionic liquid to light irradiation to induce amorphous coordination polymerization.

13. The substrate support production method according to claim 11, wherein
the gel is formed by mixing an ionic liquid and a photo-responsive gelling agent and crosslinking the gelling agent through light irradiation.

14. The substrate support production method according to claim 11, wherein
the gel is formed by mixing an ionic liquid and a heat-soluble gelling agent and crosslinking the gelling agent through heating or cooling.

15. The substrate support production method according to claim 11, wherein
the gel is formed by mixing an ionic liquid and a polymer and holding the ionic liquid by a mesh of the polymer.

16. The substrate support production method according to claim 11, wherein
the gel is formed by mixing an ionic liquid, a monomer of a radical-polymerizable compound, and a photo-radical polymerization initiator or a thermal radical polymerization initiator and crosslinking the monomer through light irradiation or heating.

17. The substrate support production method according to claim 11, wherein
the gel member is formed by gelation of an ionic liquid at the first location.

18. The substrate support according to claim 2, wherein the ionic liquid comprises a cation selected from the group consisting of pyridinium-type, imidazolium-type, ammonium-type, pyrrolidinium-type, piperidinium-type, phosphonium-type, morphonium-type, and sulfonium-type cations.

19. The substrate support according to claim 1, wherein the gel member is configured to function as a cushion member to prevent physical contact between the substrate and the support.

20. The substrate support production method according to claim 12, wherein the ionic liquid contains ruthenium (Ru) and a side chain of NC, and the gelation is induced by ultraviolet light irradiation at a wavelength of 365 nm.
